(19) United States
(12) Patent Application Publication
(10) Pub. No.: US 2026/0179716 A1
(43) Pub. Date: Jun. 25, 2026

(54) MEMORY-PAIRED SYSTEM FOR MULTIPLE STACKED SEMICONDUCTOR DEVICES AND REPAIR METHOD THEREOF

(71) Applicant: Nanya Technology Corporation, New Taipei City (TW)

(72) Inventors: Da-Zen CHUANG, Taipei City (TW); Pin-Hsiu HSIEH, New Taipei City (TW)

(73) Assignee: Nanya Technology Corporation, New Taipei City (TW)

(21) Appl. No.: 18/987,803

(22) Filed: Dec. 19, 2024

(51) Int. Cl. G11C 29/00

(52) U.S. Cl. CPC G11C 29/785; G11C 29/76

(57) ABSTRACT

This invention provides a memory-paired system for multiple stacked semiconductor devices and its repair method. The memory-paired system has a paired unit having at least two chips that are identical design. Each of the at least two chips of the paired unit has a memory resources module configured for deploying memory resources for repair and a paired control module configured for executing allocation of memory resources by sending a request to another one chip of the at least two chips of the paired unit when memory resource of the memory resource module that the request points have been allocated, or providing spare memory resource of the memory resource module to one chip of the paired unit based on a request from the one chip that has a failed unit existing, so the spare memory resource of the memory resource module repairs the failed unit of the one chip.

### BACKGROUND OF THE INVENTION

### Field of the Invention

The present invention relates to memory repair, and more particularly to a repair scheme implementing commonly sharing of spare memory resources among chips having identical design in multiple stacked semiconductor devices.

### Description of the Prior Art

With advancement of integrated circuit technology, chiplet-based packaging methods such as 2.5D, SoIC, multi-chip packaging (MCP), system-in-package (SiP), high-bandwidth memory (HBM), etc. have become increasingly popular. However, these advanced packaging technologies face several challenges that are difficult to overcome. Below describes some problems of chiplet integration in semiconductor manufacturing and packaging to be resolved.

First, as high-density packaging technology becomes more widespread, the number of chips included in a single package has significantly increased. Each chip contains a large number of circuit cells (such as memory cells), and if any of these cells have even a minor defect or slight electrical degradation due to environmental stress or accelerating factors such as high voltage or high temperature, they may eventually lead to the failure of the entire package. Since modern integrated circuit packages typically consist of chips produced with advanced technology nodes, any single chip failure can lead to the disposal of the entire package, resulting in unnecessary waste and financial loss.

Second, the increased failure rate associated with high-density packaging technology has a particularly notable impact on production yield. The costs involved in advanced packaging technologies are relatively high, including both chip costs and packaging processes. Any yield loss directly increases the overall production costs. For example, in HBM, SiP, and MCP packages, a single faulty chip in the package leads not only to the discard of that chip but also to the other chips in the package, exacerbating cost concerns.

To improve yield, the industry has proposed various solutions, particularly in memory technology. For instance, in dealing with memory failures, methods such as row repair, column repair, block repair, and global repair have been developed. These repair techniques aim to mitigate the impact of localized defects on the package. Global repair, while highly efficient and capable of addressing multiple failure scenarios, has a complex algorithm that requires a large circuit area to support it, thereby increasing the design complexity and chip area.

In addition, as process technologies continue to shrink and material properties evolve, chips within a package become more fragile. Although chiplet integration improves system integration, it also exacerbates issues related to thermal effects and stress within the package. As a result, chips are more susceptible to factors like high temperatures and voltage fluctuations, which can lead to degradation or failure during operation.

In summary, the disadvantages of chiplet integration include increased risk of yield loss in high-density packaging, greater difficulty in repair, and higher manufacturing costs. As advanced packaging techniques continue to be widely adopted, balancing integration and reliability, as well as finding effective repair solutions, will remain critical challenges for future semiconductor manufacturing.

### SUMMARY OF THE INVENTION

The present invention aims to provide a repair scheme to improve the repair efficiency without complicating the circuits, specifically for the multiple stacked semiconductor devices. The repair scheme can be executed after chips stacking, for example 3D stacking, to benefit the yield improvement.

The present invention provides a repair method for multiple stacked semiconductor devices. According to a repair process of the present method, initially configuring at least two chips having identical design as a paired unit in multiple stacked semiconductor devices. A request from one chip of the paired unit sends to another one chip of the paired unit once the one chip has a failed unit existing in it and resource of the one chip to repair the failed unit has been allocated. The request points a required resource to repair the failed unit. A spare resource from the another one chip of the paired unit is allocated to the one chip having the failed unit of the paired unit based on the request.

The repair method further comprises remapping resources of the another one chip of the paired unit when the another one chip of the paired unit receives the request; notifying an information of resource remapping of the another one chip of the paired unit to the one chip having the failed unit of the paired unit; and remapping resources of the one chip having the failed unit of the paired unit based on the information to correspond to a resource state of the one chip having the failed unit of the paired unit receiving the spare resource from the another one chip of the paired unit.

In an implementation of the present invention, the multiple stacked semiconductor devices comprises one or more paired units, the chips among the paired units are different designs.

In an implementation of the present invention, the repair method further comprises assigning an individual identification to each chip of the paired unit and correlating the paired unit to a set of the individual identifications assigned to the chips grouped in the paired unit. The one chip having the failed unit of the paired unit identifies the another one chip of the paired unit according to the set of the individual identifications and vice versa.

In an implementation of the present invention, the one chip having the failed unit of the paired unit sends the request to the another one chip of the paired unit according to order of the individual identifications.

In an implementation of the present invention, the one chip having the failed unit of the paired unit sends a next request to a next another one chip of the paired unit according to the order of the individual identifications if the another one chip of the paired unit does not have spare resource to be allocated to the one chip. The next request points the required resource to repair the failed unit of the one chip.

In an implementation of the present invention, a stacked number of the chips of the paired unit is even or odd.

The present invention further provides a memory-paired system for multiple stacked semiconductor devices, comprising: a paired unit having at least two chips that are identical design, wherein each of the at least two chips of the paired unit includes a memory resources module configured for deploying memory resources for repair; and a paired control module configured for executing allocation of memory resources by sending a request to another one of the at least two chips of the paired unit when memory resource of the memory resource module that the request points have been allocated, or providing spare memory resource of the memory resource module to one chip of the paired unit based on a request from the one chip that has a failed unit existing so that the spare memory resource of the memory resource module repairs the failed unit of the one chip.

In an implementation of the present invention, the paired control module comprises a resource remapping module configured for remapping the memory resources of the memory resource module based on the request from the one chip having the failed unit of the paired unit; and a resource management module configured for notifying an information regarding remapping memory resources of the remapping module to the one chip having the failed unit of the paired unit, wherein the resource management module of the one chip having the failed unit of the paired unit instructs a resource remapping module of it to remap memory resources of a memory resource module of it based on the information, so that the spare memory resource from the chip of the paired unit is allocated to the one chip having the failed unit to repair the failed unit.

In an implementation of the present invention, the paired control module further comprises a paired ID module configured for storing a set of identifications that correlate the at least two chips of the paired unit, each of the at least two chips is assigned an individual identification among the identifications; and the one chip having the failed unit of the paired unit identifies the another chip of the paired unit according to the set of the identifications and vice versa.

### BRIEF DESCRIPTION OF THE DRAWINGS

The foregoing and other features and advantages of the example embodiments of the present invention will become more apparent upon consideration of certain example embodiments of the inventive concepts illustrated in accompanying drawings. The drawings are not necessarily to scale, but emphasize certain features and principles of the example embodiments of the inventive concepts. Throughout the drawings and written description, like reference numbers and labels are used to denote like or similar elements and features. In the drawings:

FIG. 1 is a schematic diagram of a memory-paired system for multiple stacked semiconductor devices according to an embodiment of the present invention.

FIG. 2 is a schematic flowchart of a repair method for multiple stacked semiconductor devices according to an embodiment of the present invention.

FIGS. 3A-3D show schematic diagrams of first variances of paired units of the present invention.

FIGS. 4A-4C show schematic diagrams of second variances of paired units of the present invention.

FIGS. 5A-5B show schematic diagrams of third variances of paired units of the present invention.

### DETAILED DESCRIPTION OF THE PREFERRED EMBODIMENTS

Hereinafter, exemplary embodiments of the present inventive concept will be described in detail with reference to the accompanying drawings. The exemplary embodiments of the present inventive concept are provided so that this disclosure will be thorough and complete, and will fully convey the present inventive concept to one of ordinary skill in the art. Since the inventive concept may have diverse modified embodiments, exemplary embodiments are illustrated in the drawings and are described in the detailed description of the inventive concept. However, this does not limit the present inventive concept within specific embodiments and it should be understood that the present inventive concept covers all the modifications, equivalents, and replacements within the idea and technical scope of the present inventive concept. Like reference numerals may refer to like elements throughout. In the drawings, the dimensions and size of each structure may be exaggerated, reduced, or schematically illustrated for convenience in description and clarity.

Terms like “first”, “second” . . . etc., they may be used to describe various elements, but the elements should not be limited by the terms. The terms may be used only as purpose for distinguishing an element from another element.

It will be understood that, although the terms first, second, third, etc. may be used herein to describe various elements, components, regions and/or sections, these elements, components, regions and/or sections should not be limited by these terms. These terms are only used to distinguish one element, component, region or section from another element, component, region or section. Thus, a first element, component, region or section discussed below could be termed a second element, component, region or section without departing from the teachings of the example embodiments of the inventive concepts.

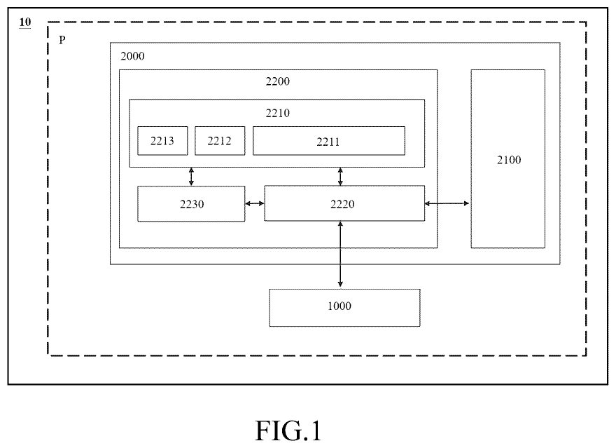

One embodiment of the present disclosure, as shown in FIG. 1, provides a memory-paired system 10 for multiple stacked semiconductor devices (not shown), including a paired unit P having chip1 1000 and chip2 2000 that are identical design. The chip1 1000 and chip2 2000 of the paired unit P may have storage function and referred to as a memory chip, for example, a dynamic random access memory (DRAM), a static random access memory (SRAM), ferroelectric random access memory (FRAM), any choice of volatile memory, non-volatile memory (NVM) or memory blocks in a logic IC, or the like. The chip1 1000 and chip2 2000 of the paired unit P may be disposed hierarchically in a 3D stacking manner. A logic IC is located at a bottom layer. The chip1 1000 and chip2 2000 of the paired unit P are located above the logic IC to form the multiple stacked semiconductor devices. The chip2 2000 of the paired unit P includes a memory resources module 2100 and a paired control module 2200. The chip1 1000 has a memory resources module and a paired control module similar to that of the chip2 2000 since the chip1 1000 has a similar configuration as chip2 2000,

The memory resources module 2100 is configured for deploying memory resources of the chip2 2000 for repairing localized failure of the paired unit P, for example a failed unit existing in the chip2 2000 itself or a failed unit existing in another one chip of the paired unit P such as a failed unit existing in the chip1 1000. The memory resources may include redundancy, extra cells, programmable register, specific logic circuits, fuses or any reserved block or function, etc. but not limited to the above described. The paired control module 2200 is configured for executing allocation of memory resources of the chip2 2000 and communicates with the memory resources module 2100 and other memory chips of the paired unit P like the chip1 1000. The paired control module 2200 may send a request to the chip1 1000 of the paired unit P when memory resource of the memory resources module 2100 that the request points have been allocated to ask for sharing memory resource from the chip1 1000 to repair a localized failure of the chip2 2000, as the request points. The paired control module 2200 may receive a request from the chip1 1000 of the paired unit P that has a failed unit existing and provides spare memory resource of the memory resources module 2100 to the chip1 1000 to allocate the spare memory resource of the memory resources module 2100 to repair the failed unit of the chip1 1000.

The paired control module 2200 of the chip2 2000 of the paired unit P has a pair information module 2210, a resource management module 2220 and a pair decoder 2230. The pair information module 2210 comprises a resource remapping module 2211, a paired ID module 2212 and a paired size module 2213. The pair information module 2210 may be configured in non-volatile memory (NVM), or One-Time Programmable Memory (OTP) for reading, processing and storing information. The resource management module 2220 communicates with the pair information module 2210 and the memory resources module 2100. According to the present disclosure, the communication among chips within one common paired unit is via respective resource management modules of the chips of the common paired unit. The resource management module 2220 further communicates with the pair information module 2210 via the pair decoder 2230 so that the resource management module 2220 can select and activate a specific chip of the paired unit P based on the input of the resource management module 2220 to the pair decoder 2230.

The resource remapping module 2211 is configured for remapping the memory resources of the memory resources module 2100 according to an input from the resource management module 2220. For example, the resource remapping module 2211 may remap the resources of the memory resources module 2100 based on the request from the chip1 1000 having the failed unit existing of the paired unit P via the resource management module 2220. So, the chip2 2000 may release spare memory resource of the memory resources module 2100 as the request asks for to repair the failed unit of the chip1 1000. The resource management module 2220 notifies an information regarding remapping memory resources of the resources remapping module 2211 to the one chip1 1000 having the failed unit of the paired unit P. A resource management module (not shown) of the chip1 1000 having the failed unit of the paired unit P instructs a resource remapping module (not shown) of it to remap memory resources of a memory resource module (not shown) of it based on the information. Therefore, the spare memory resource from the chip2 2000 of the paired unit P is allocated to the chip1 1000 having the failed unit to repair the failed unit.

The paired ID module 2212 is configured for storing a set of identifications that correlate the chip1 1000 and chip2 2000 of the paired unit P. Each of the chip1 1000 and chip2 2000 is assigned an individual identification among the identifications, and the chip1 1000 having the failed unit of the paired unit P identifies one another chip of the paired unit P, for example the chip2 2000 according to the set of the identifications, and vice versa. According to the present disclosure, each of chips of a common paired unit has its individual paired ID module to store a set of individual identifications assigned to the chips and each of the chips can identify the other chips of the common paired unit according to the set of identifications.

The paired size module 2213 is configured for supporting error correction and redundancy, optimizing the physical layout of storage cells for maximum storage density, especially in advanced technologies like 3Ds stacking. The pair decoder 2230 is configured for decoding an input information of the request received by the resource management module 2220. Then, the resource management module 2220 can select and activate a specific chip of the paired unit P based on the data storing in the paired ID module 2212 and the paired size module 2213, and remaps the resource of the memory resources module 2100.

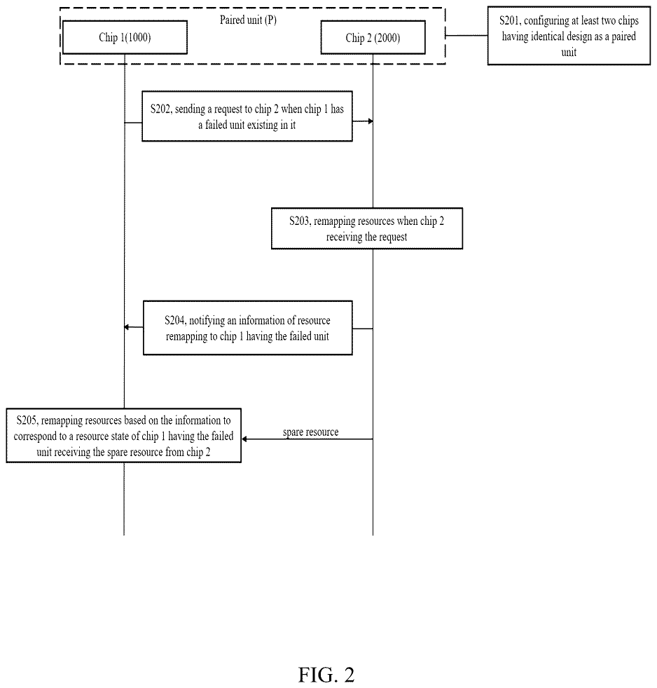

As shown in FIG. 2, embodiments of the present disclosure may execute following steps for repairing a localized failure existing in a common paired unit comprised of two or more memory chips that are identical design.

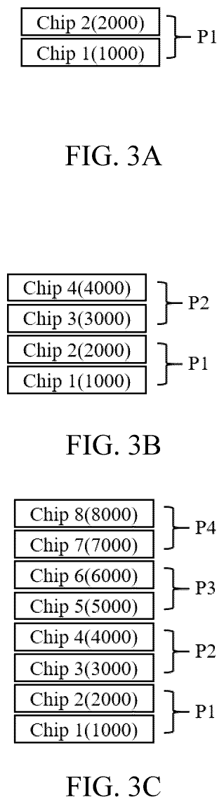

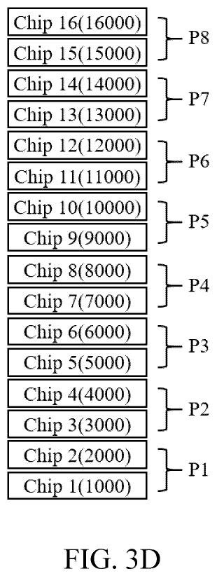

At S201 step: configuring at least two chips having identical design as a paired unit in the multiple stacked semiconductor devices and assigning an individual identification to each of the chips of the paired unit, and correlating the paired unit to a set of the individual identifications assigned to the chips grouped in the paired unit. For example, as shown in FIG. 3A, the chip1 1000 and the chip2 2000 are grouped in the paired unit P. Each of the chip1 1000 and the chip2 2000 is assigned its individual identification. The chip1 1000 and the chip2 2000 may be integrated in the paired unit P by 3D technologies to form the memory-paired system 10, as shown in FIG. 1. Either of the chip1 1000 and the chip2 2000 identifies one another chip of the paired unit P according to the set of the individual identifications. In embodiments of the present disclosure, a number of chips grouped in a common pair unit may even or odd, like 2, 3, 4, 5, . . . , 8, 9, . . . , 16 that are identical design. The multiple stacked semiconductor devices of present disclosure may comprise one or more paired units that may be heterogeneous or homogeneous integration among the paired units. The number of the chips in one common paired unit and the number of paired units of present disclosure may depend on 3D stacking design requirement.

Take an example, as shown in FIG. 3B, the multiple stacked semiconductor devices of present disclosure may include four chips called Chip1 1000, Chip2 2000, Chip3 3000 and Chip4 4000. Chip1 1000 and Chip2 2000 are configured as first paired unit P. Chip3 3000 and Chip4 4000 are configured as second paired unit P2. The first paired unit P1 may be DRAM and the second paired unit P2 may be SRAM, or other memory types. In this scenario, a paired ID module of each of the chip1 1000 and chip2 2000 stores a set of individual identifications assigned to the chips grouped in the paired unit P1. A paired ID module of each of the chip3 3000 and chip4 4000 stores a set of individual identifications assigned to the chips grouped in the paired unit P2. Thus, the chip1 1000 of the paired unit P1 can identify the chip2 2000 of the first paired unit P1 according to the set of the individual identifications and vice versa rather than the chip3 3000 or the chip4 4000.

At S202 step: the chip1 1000 sends a request to the chip2 2000 of the paired unit P when the chip1 1000 has a failed unit existing in it and resource of the chip1 1000 itself to repair the failed unit has been allocated or used up. The request points a required resource to repair the failed unit of the chip1 1000. For example, the resource remapping module of the chip1 1000 finds resource of the memory resources module of the chip1 1000 itself to repair the failed unit is used up, the chip1 1000 sends a request via its resource management module to the chip2 2000 of the paired unit P to ask for allocating a spare resource of the chip2 2000 to the chip1 1000 to repair the failed unit. In this embodiment of present disclosure, the chip1 1000 and the chip2 2000 communicate with each other via their respective resource management modules. In this embodiment, the resource management module of the chip1 1000 sends the request to ask for spare resource from the chip2 2000, and the resource management module 2220 of the chip2 2000 receives the request and then releases the spare resource if have. According to the present disclosure, if a chip of a common paired unit has a failed unit existing and its memory resource for repairing the failed unit is used up, the chip may send a request according to order of identifications of the other chips to ask for releasing spare resource from one of them to repair its failed unit.

At S203 step: the resource remapping module 2211 of the chip2 2000 of the paired unit P remaps resources of the memory resources module 2100 when the resource management module 2220 of the chip2 2000 receives the request.

At S204 step: the resource management module 2220 of the chip2 2000 notifies an information of resource remapping of the chip2 2000 to the chip1 1000 of the paired unit P. More specifically, the chip1 1000 and the chip2 2000 communicate information through their respective resource management module. In this embodiment, the resource management module 2220 of the chip2 2000 notifies an information of resource remapping of the chip2 2000, and the resource management module of the chip1 1000 receives the information.

At S205 step: the memory resources module of the chip1 1000 remaps resources based on the information to correspond to a resource state of the chip1 1000 that receives the spare resource of the memory resources module 2100 from the chip2 2000. Hence, the failed unit of the chip1 1000 can be repaired by the spare resource of the chip2 2000.

In a case that more than two chips are grouped in a common paired unit, one chip having a failed unit of the common paired unit may send a next request to a second another one chip of the common paired unit according to order of individual identifications assigned to the chips of the common paired unit if a first another one chip of the paired unit does not have spare resource to be allocated to the one chip. The next request points the required resource to repair the failed unit of the one chip. The process steps from S202 to S205 are executed between the one chip and the second another chip of the common paired unit.

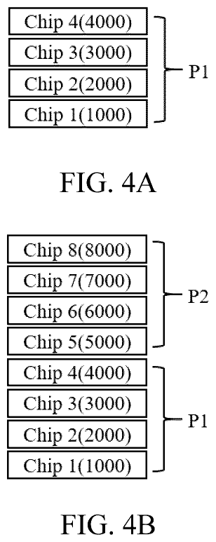

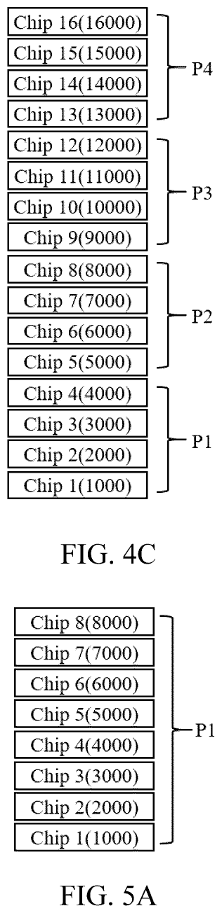

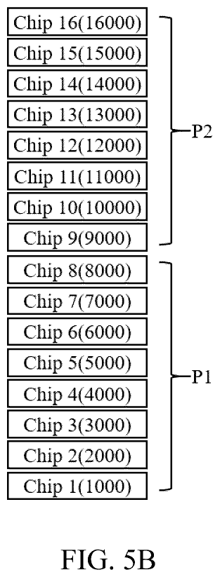

As shown in FIGS. 3A-3D, in first variances of paired units of the present disclosure, the multiple stacked semiconductor devices may have the stacked number of the chips from two to sixteen, and every two identical chips among the chips may bind together in one paired unit. Further, in second variances of paired units of the present disclosure, as shown in FIGS. 4A-4C, every four identical chips among the chips may bind together in one paired unit. In third variances of paired units of the present disclosure, as shown in FIGS. 5A-5B, every eighth identical chips among the chips may bind together in one paired unit. The multiple stacked semiconductor devices may comprise one or more paired units, and the chips among the paired units may different designs or identical design to allow heterogeneous or homogeneous integration among the paired units. Take the configuration of FIG. 4C for illustrating the heterogeneous integration among the paired units of the present disclosure. Chip1 1000, chip2 2000, chip3 3000 and chip4 4000 in first paired unit P1 may be DRAM. Chip5 5000, chip6 6000, chip7 7000 and chip8 8000 in second paired unit P2 may be SRAM. Chip9 9000, chip10 10000, chip11 11000 and chip12 12000 in third paired unit P3 may be MRAM. Chip13 13000, chip14 14000, chip15 15000 and chip16 16000 in fourth paired unit P4 may be other memory type.

According to the method or system of the present disclosure, while the chip1 1000 and the chip2 2000 are grouped in a paired unit, the algorithm allows these chips sharing the same global repair, that is, the chip1 1000 can use the resources of the chip2 2000 and vice versa. The resource can be redundancy, extra cells, programmable register, specific logic circuits, fuses or any reserved block or function, etc, but not limited to the above described. Moreover, a dead chip has a chance to become alive by using resources of other chips in the common paired unit of the present disclosure. Based on this, a circuit structure of the chips is greatly simplified.

The above-mentioned embodiments of the present invention are exemplary and not intended to limit the scope of the present invention. Various variation or modifications made without departing from the spirit of the present invention and achieving equivalent effects shall fall within the scope of claims of the present invention.

1. A repair method for multiple stacked semiconductor devices, comprising:
configuring at least two chips having identical design as a paired unit in the multiple stacked semiconductor devices;
sending a request from one chip of the paired unit to another one chip of the paired unit, wherein the one chip has a failed unit existing in it and resource of the one chip to repair the failed unit has been allocated, the request points a required resource to repair the failed unit;
allocating a spare resource from the another one chip of the paired unit to the one chip having the failed unit of the paired unit based on the request.

2. The repair method of claim 1, further comprising:
remapping resources of the another one chip of the paired unit when the another one chip of the paired unit receiving the request;
notifying an information of resource remapping of the another one chip of the paired unit to the one chip having the failed unit of the paired unit;
remapping resources of the one chip having the failed unit of the paired unit based on the information to correspond to a resource state of the one chip having the failed unit of the paired unit receiving the spare resource from the another one chip of the paired unit.

3. The repair method of claim 1, wherein the multiple stacked semiconductor devices comprise one or more pair units, the chips among the pair units are different designs.

4. The repair method of claim 1, further comprising:
assigning an individual identification to each chip of the pair unit and correlating the pair unit to a set of the individual identifications assigned to the chips grouped in the pair unit; wherein the one chip having the failed unit of the paired unit identifies the another one chip of the paired unit according to the set of the individual identifications.

5. The repair method of claim 4, wherein the one chip having the failed unit of the paired unit sends the request to the another one chip of the paired unit according to order of the individual identifications.

6. The repair method of claim 5, further comprising:
sending a next request from the one chip having the failed unit of the paired unit to a next another one chip of the paired unit if the another one chip of the paired unit does not have spare resource to be allocated to the one chip having the failed unit of the paired unit to repair the failed unit according to the order of the individual identifications, wherein the next request points the required resource to repair the failed unit of the one chip.

7. The repair method of claim 1, wherein a stacked number of the chips of the paired unit is even or odd.

8. A memory-paired system for multiple stacked semiconductor devices, comprising:
a paired unit having at least two chips that are identical design;
wherein each of the at least two chips of the paired unit includes:
a memory resources module, configured for deploying memory resources for repair;
a paired control module, configured for executing allocation of memory resources by:
sending a request to another one chip of the at least two chips of the paired unit when memory resource of the memory resource module that the request points have been allocated; or
providing spare memory resource of the memory resource module to one chip of the paired unit based on a request from the one chip that has a failed unit existing so that the spare memory resource of the memory resource module repairs the failed unit of the one chip.

9. The memory-paired system of claim 8, wherein the paired control module comprises:
a resource remapping module, configured for remapping the memory resources of the memory module based on the request from the one chip having the failed unit of the paired unit;
a resource management module, configured for notifying an information regarding remapping memory resources of the resource remapping module to the one chip having the failed unit of the paired unit;
wherein the resource management module of the one chip having the failed unit of the paired unit instructs a resource remapping module of it to remap memory resources of a memory resource module of it based on the information, so that the spare memory resource from the another one chip of the paired unit is allocated to the one chip having the failed unit to repair the failed unit.

10. The memory-paired system of claim 9, wherein the paired control module further comprises a paired ID module configured for storing a set of identifications that correlate the at least two chips of the paired unit, each of the at least two chips is assigned an individual identification among the identifications; and the one chip having the failed unit of the paired unit identifies the another one chip of the paired unit according to the set of the identifications.

11. The memory-paired system of claim 10, wherein the one chip having the failed unit of the paired unit sends the request to the another one chip of the paired unit according to order of the identifications.

12. The repair system of claim 8, wherein a stacked number of the at least two chips of the paired unit is even or odd.

13. The repair method of claim 3, further comprising:
assigning an individual identification to each chip of the pair unit and correlating the pair unit to a set of the individual identifications assigned to the chips grouped in the pair unit; wherein the one chip having the failed unit of the paired unit identifies the another one chip of the paired unit according to the set of the individual identifications.
